(19) United States
(12) Patent Application Publication
(10) Pub. No.: US 2025/0259880 A1
(43) Pub. Date: Aug. 14, 2025

(54) SUSCEPTOR FOR A SILICON CARBIDE SUBSTRATE

(71) Applicant: Applied Materials, Inc., Santa Clara, CA (US)

(72) Inventors: Peter DEMONTE, Santa Clara, CA (US); Rajagopal MURUGESAN, Bangalore (IN); Wolfgang R. ADERHOLD, Cupertino, CA (US)

(21) Appl. No.: 18/438,621

(22) Filed: Feb. 12, 2024

(51) Int. Cl. H01L 21/687

(52) U.S. Cl. CPC H01L 21/68785; H01L 21/68742; H01L 21/68757

(57) ABSTRACT

Disclosed herein are a detachable part of a susceptor, a susceptor including the detachable part, and a substrate support assembly including the susceptor. The susceptor includes a plurality of cutouts coupled with the detachable part that includes an arc-shaped rim. The arc-shape rim includes an inner diameter, an outer diameter that is greater than the inner diameter, a first top surface, and a first bottom surface. The detachable part further includes a plurality of protrusions disposed along the inner diameter of the arc-shaped rim. The plurality of the protrusions include a second top surface that is disposed below the first top surface. When the susceptor is included in the substrate support assembly, a cylindrical ring is coupled with both a body of the substrate support assembly and the susceptor.

### BACKGROUND

### Field

The present disclosure generally relates to a susceptor for processing a transparent substrate in a processing chamber. More particularly, embodiments of the present disclosure relate to a susceptor comprising a detachable lift ring for processing a silicon carbide substrate in a processing chamber.

### Description of the Related Art

In recent years, silicon carbide (SiC) substrates have gaining popularities in semiconductor devices, such as power devices for high voltages. SiC offers many advantages comparing to silicon. For example, SiC has a larger band gap and higher breakdown electric field strength than those of silicon. As a result, semiconductor devices made from SiC can operate at a higher voltage, over a wider temperature range, and with a faster switching frequency.

SiC substrates are known to be transparent to light wavelengths commonly used for heating substrates in a processing chamber. As a result, processing SiC substrates efficiently and rapidly is challenging when using conventional semiconductor processing chambers. Moreover, as SiC substrates allow heating light to pass through, the heating light that has passed (e.g., leaking) through the substrate can sometime interfere with measurements of thermal sensors in the processing chamber.

Accordingly, there is a need to have an improved susceptor and a semiconductor processing chamber for processing SiC substrates.

### SUMMARY

Disclosed herein are a detachable part of a susceptor, a susceptor including the detachable part, and a substrate support assembly including the susceptor. The detachable part includes an arc-shaped rim. The arc-shape rim includes an inner diameter, an outer diameter that is greater than the inner diameter, a first top surface, and a first bottom surface including a plurality of depressions shaped like a frustum. The detachable part further includes a plurality of protrusions disposed along the inner diameter of the arc-shaped rim. The plurality of the protrusions include a second top surface that is disposed below the first top surface.

According to an example of the present application, the susceptor includes a detachable part detachably coupled with a base part. The base part includes a plurality of cutouts configured to couple with side surfaces of the detachable part. The detachable part includes an arc-shaped rim with an inner diameter, an outer diameter that is greater than the inner diameter, a first top surface, and a first bottom surface having a plurality of depressions shaped like a frustum. The detachable part further includes a plurality of protrusions disposed along the inner diameter of the arc-shaped rim and having a second top surface that is disposed below the first top surface.

According to another example of the present application, a substrate support assembly includes a body surrounded by a cylindrical ring and a susceptor coupled with the cylindrical ring. The body includes a plurality of pin holes. The susceptor includes a detachable part detachably coupled with a base part that includes a plurality of cutouts whose side surfaces are configured to couple with side surfaces of the detachable part. The detachable part of the susceptor includes components and configurations as described in the present application.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic cross-sectional view of a processing chamber, according to an embodiment of the present application.

FIG. 3 illustrates a schematic cross-sectional view of a substrate support assembly, according to an embodiment of the present application.

FIG. 4 illustrates a schematic perspective view of a susceptor, according to an embodiment of the present application.

FIG. 5 illustrates a schematic perspective view of a susceptor, according to an embodiment of the present application.

FIG. 6 illustrates a schematic cross-sectional view of the susceptor when the detachable part engages with the base part, according to an embodiment of the present application.

FIG. 7a illustrates a schematic cross-sectional view of the susceptor when the detachable part is lifted up from the base part, according to an embodiment of the present application.

FIG. 7b illustrates a schematic cross-sectional view of a coupling mechanism between the base part and the cylindrical ring, according to an embodiment.

FIG. 8 illustrates a schematic bottom view of the detachable part, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are a detachable part of a susceptor, a susceptor including the detachable part, and a substrate support assembly including the susceptor. The detachable part, the susceptor, and the substrate support assembly can be included in a processing chamber for processing silicon carbide substrates. The susceptor and the detachable part are opaque, which are capable of absorbing the heating light utilized by the processing chamber. For example, the susceptor and the detachable part are made of graphite and coated with a layer of silicon carbide. Other layers may be additionally deposited on the surfaces of the susceptor that can protect the susceptor from the processes. These other layers may include polysilicon, an oxidation layer of silicon carbide, or any other suitable layers. In another example, the susceptor and the detachable part are made of silicon carbide, which is further coated by an oxidation layer of the silicon carbide.

The detachable part of the susceptor can be lifted up from a base part. The detachable part engages with both the substrate and lift pins. When the lift pins raises the detachable part from the base part, the detachable part lifts up the substrate that is sitting on surfaces of the detachable part. The detachable part has a plurality of depressions, which are blind holes and disposed at the bottom surface of the detachable part. The depressions are aligned with pin holes in a substrate support assembly. Even when the detachable part is lifted from the base part, the blind holes and surrounding opaque materials still block heating light from entering the pin holes of the substrate assembly. When a substrate support assembly includes a susceptor as described in the present application, the heating light of the processing chamber can heat the substrate more efficiently as leakage of the heating light through pin holes is substantially prevented.

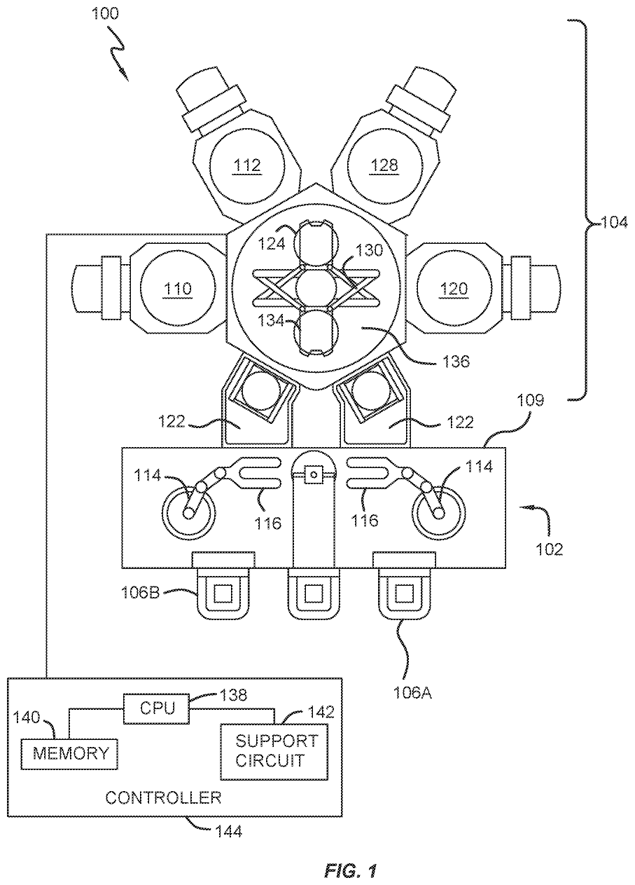

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 includes a CENTURA® integrated processing system, provided by Applied Materials, Inc., located in Santa Clara, California. The one or more load lock chambers may include a rapid thermal processing (RTP) chamber, an epitaxial growth chamber, an etch chamber, and etc. It is contemplated that other processing systems (including those from other manufacturers) may be adapted to benefit from the disclosure.

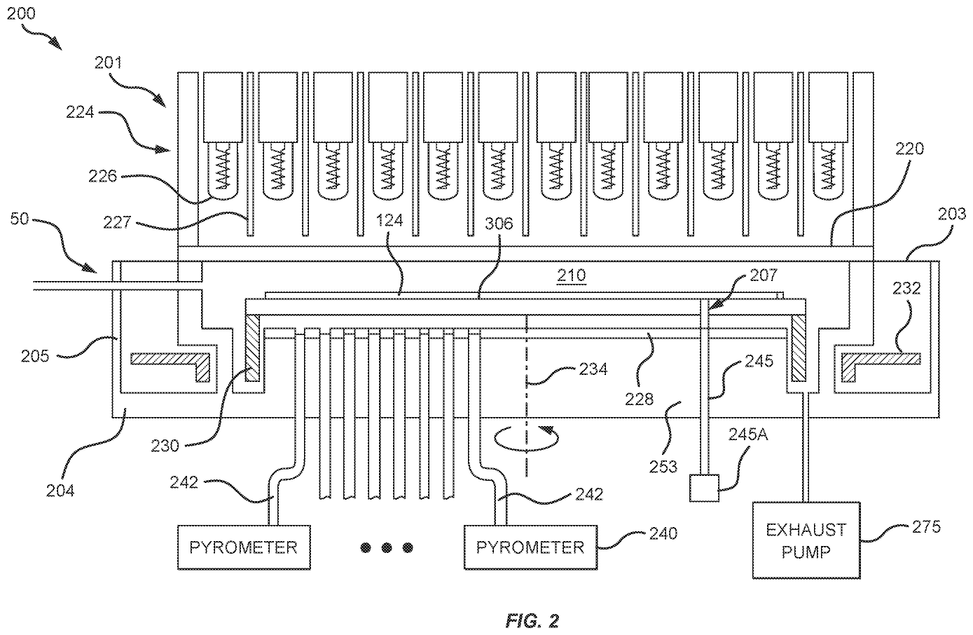

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. According to an embodiment, one or more of the plurality of processing chambers 110, 112, 120, and 128 may be a low temperature EPI chamber, a plasma etch chamber, a chemical vapor deposition chamber, or other processing chamber. At least one of the processing chambers 110, 112, 120, and 128 includes a substrate support assembly 300 including a susceptor (shown in FIG. 2) and configured to process a silicon carbide substrate according to an embodiment of the present application.

Continuing to refer to FIG. 1, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

Each of the load lock chambers 122 has a first port interfacing with the factory interface 102 and a second port interfacing with the transfer chamber 136. The load lock chambers 122 are coupled to a pressure control system (not shown) which pumps down and vents the load lock chambers 122 to facilitate passing the substrates between the environment (e.g., vacuum environment or ambient environment, such as atmospheric environment) of the transfer chamber 136 and a substantially ambient (e.g., atmospheric) environment of the factory interface 102.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The controller 144 is coupled to the processing system 100 and is used to control processes and methods, such as the operations of the methods described herein (for example the operations of the methods as described in other parts of the present application). The controller 144 includes a central processing unit (CPU) 138, a memory 140 containing instructions, and support circuits 142 for the CPU. The controller 144 controls various items directly, or via other computers and/or controllers.

FIG. 2 illustrates a schematic cross-sectional view of a processing chamber 200, according to an embodiment. The processing chamber 200 can be one or more of the processing chambers 110, 112, 120, and 128 as shown in FIG. 1. In an embodiment, the processing chamber 200 functions as an RTP chamber configured to rapidly heat a substrate 124 to a processing temperature. The substrate 124 may be a transparent substrate, such as a SiC substrate, although non-transparent substrates may also be processed by the processing chamber 200.

The RTP chamber 201 includes a chamber body 50 enclosing an interior volume 210. Process gases are provided into the interior volume 210, and an exhaust pump 275 removes exhaust gases the RTP chamber 201. The chamber body 50 includes a top 203, a bottom 204, and one or more sides 205 connecting the top 203 with the bottom 204. The RTP chamber 201 includes a transparent window 220 that can form part of the top 203 of the chamber body 50. The RTP chamber 201 includes a rotatable flange 232. A rotor (not shown) rotates the rotatable flange 232 about the central axis 234.

The RTP chamber 201 includes a susceptor 306 coupled with a cylindrical ring 230. The susceptor 306 supports the substrate 124. In an embodiment, the susceptor 306 has a plurality of pin holes 207 covered by a detachable part. The substrate 124 can be lifted up or lowered down by the lift pins 245. In an embodiment, the cylindrical ring 230 may be magnetically coupled to the rotatable flange 232. Thus, the rotation of the flange 232 can cause the cylindrical ring 230 to rotate, which, in turn, causes the substrate 124 and the susceptor 306 that are positioned on the cylindrical ring 230 rotate. In an embodiment, the susceptor 306 and the cylindrical ring 230 may be rotated independently from the flange 232.

The RTP chamber 201 further includes a heating apparatus 224 positioned above the susceptor 306. The heating apparatus 224 can include a plurality of lamps 226 disposed within reflective tubes. In an embodiment, the plurality of lamps 226 include high-intensity tungsten-halogen lamps arranged in a hexagonal close-packed array above the transparent window 220. The heating apparatus 224 can rapidly heat the substrate 124 in the interior volume 210 at rates greater than 100° C./second to temperatures as high as 1500° C.

The RTP chamber 201 further includes a reflector 228 positioned below the susceptor 306 and supported on a base 253. The reflector 228 can be used to reflect radiation back towards the substrate 124 and susceptor 306. The reflector 228 can include holes that allow the lift pins 245 to extend and retract through the reflector 228 to raise and lower the susceptor 306. Each lift pin 245 can be connected to a lift pin actuator 245A, positioned below the reflector 228.

The RTP chamber 201 can further include a plurality of pyrometers 240, each coupled with a light pipe 242 that extends from a pyrometer to a location below the susceptor 306. The pyrometers 240 are configured to receive radiation by the susceptor 306 through light pipes 242 to monitor temperatures at different locations (e.g., different radial locations) on the substrate 124. When a silicon carbide substrate is processed in the RTP chamber 201, light emitted by the lamps 226 may leak through the pin holes of the susceptor 306 because the silicon carbide substrate is transparent to the light emitted by the lamps 226. As a result, the measurement of the pyrometers can be interfered and may not reflect an actual temperature of the susceptor 306.

According to an embodiment, the susceptor 306 is configured to block light emitted by lamps 226 from leaking through the pin holes 207. In an example, the susceptor 306 is made of an opaque material that can block the light emitted by the lamps 226. The opaque material may include graphite, black quartz, or any other suitable materials. The susceptor 306 may have coatings covering the opaque material. The coating may be made of silicon carbide.

According to an embodiment, the pin holes 207 do not pass through all parts of the susceptor 306. In an example, the susceptor 306 includes a detachable part sitting on a base part. The pin holes 207 may be disposed in the base part. The detachable part does not have pin holes and is configured to covers the plurality of pin holes 207. When the substrate 124 is lifted up by the lift pins 245, the detachable part is configured to move with the substrate 124. Thus, when pin holes 207 are exposed after the substrate 124 is raised, the detachable part is still positioned right above the pin holes 207 and is configured to block light of the lamps 226 from leaking through the pin holes 207.

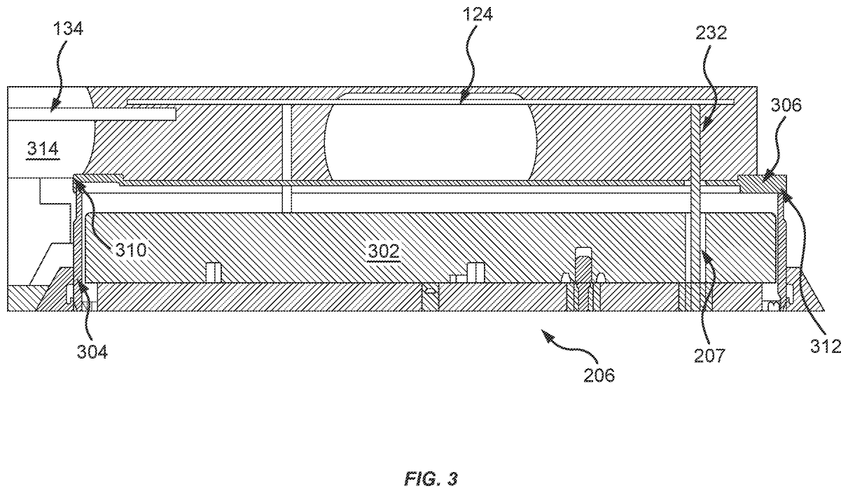

FIG. 3 illustrates a schematic cross-sectional view of a substrate support assembly 300 having a susceptor 306, according to an embodiment. The substrate support assembly 300 includes a body 302, a cylindrical ring 304, and a susceptor 306. The body 302 includes a plurality of pin holes 207 that allow lift pins 232 to pass through. The cylindrical ring 304 encloses the body 302 and supports the susceptor 306 via a top surface 310 of the cylindrical ring 304. The susceptor 306 includes a skirt 312 that overlaps with the cylindrical ring 304.

According to an embodiment, the cylindrical ring 304 and the susceptor 306 includes a material which is opaque to the radiation emitted by the heating apparatus 224. The opaque material may include graphite, black quartz, polysilicon, or any other suitable materials. The opaque material may be used as a body of the susceptor 306 or a surface layer of the susceptor 306. In an example, the cylindrical ring 304 is made of black quartz. In another example, the susceptor 306 includes a body made of graphite and a surface layer of silicon carbide covering the graphite. A layer of polysilicon or oxidized silicon carbide may also be further included to cover the silicon carbide. In another example, the susceptor 306 includes a body made of silicon carbide and a layer of polysilicon covering the silicon carbide. In yet another example, the susceptor 306 includes a body made of silicon carbide and an oxidation layer of the silicon carbide.

As shown in FIG. 3, the substrate 124 is lifted to a position spaced above the susceptor 306. A blade 134 can be extended under the lifted substrate 124 through a door 314 of the processing chamber 200. The substrate 124 can be transferred from the lift pin 232 to the blade 134. The blade 134 may the move the substrate 124 out of the processing chamber 200 via the door 314.

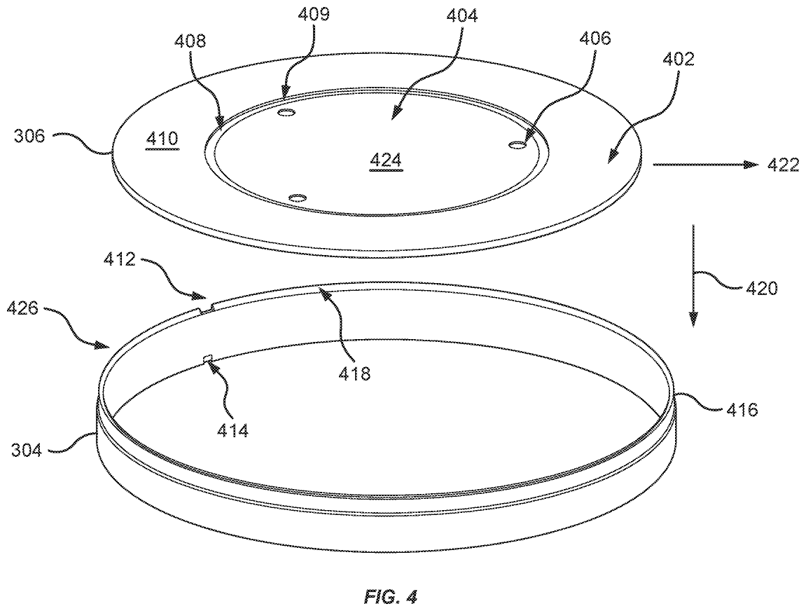

FIG. 4 illustrates a perspective view of a cylindrical ring 304 and a susceptor 306, according to an embodiment. The cylindrical ring 304 is substantially annular and extends along a vertical direction 420, which is perpendicular to a horizontal plane 422 defined by a top surface 424 of an inner pocket 404 of the susceptor 306. The height 416 of the cylindrical ring 304 is greater than that of the body 302 (shown in FIG. 3). The cylindrical ring 304 includes a plurality of notches 412 disposed at an upper circumference 426 of the cylindrical ring 304. The plurality of notches 412 are configured to align the susceptor 306 with the cylindrical ring 304 and retain the susceptor 306 on the cylindrical ring 304. The cylindrical ring 304 includes a plurality of notches 414 disposed at a bottom surface of the cylindrical ring 304. The plurality of notches 414 are configured to align the cylindrical ring 304 with the body 302 and retain the cylindrical ring 304 on the body 302. The cylindrical ring 304 further includes a chamfered surface 418 disposed along the upper circumference 426 of the cylindrical ring 304 and inclined inwardly toward a center of the cylindrical ring 304.

The susceptor 306 is substantially annular and includes an inner pocket 404, a base rim 402 surrounding and coupled to the inner pocket 404, and a transitional rim 408 disposed between the inner pocket 404 and the base rim 402. The inner pocket 404 may be slightly lower than a top surface 410 of the base rim 402. The inner pocket 404 is sized to receive the substrate 124 such that the substrate 124 fits just inside the base rim 402. The inner pocket 404, the base rim 402, and the transitional rim 408 are configured to prevent the substrate 124 from slipping out during processing. The inner pocket 404 is provided with a number of pin holes 406, for example three (3) pin holes, corresponding to the placement of pin holes 207 of the body 302 (shown in FIG. 3). In one example, the pin holes 406 may be arranged at 120 degree intervals along the circumference of the inner pocket 404.

The transitional rim 408 may have an angled surface 409. The angled surface 409 may be inclined toward the inner pocket 404. The angled surface 409 may be angled between about 2 degrees to about 20 degrees, such as about 6 degrees to about 15 degrees.

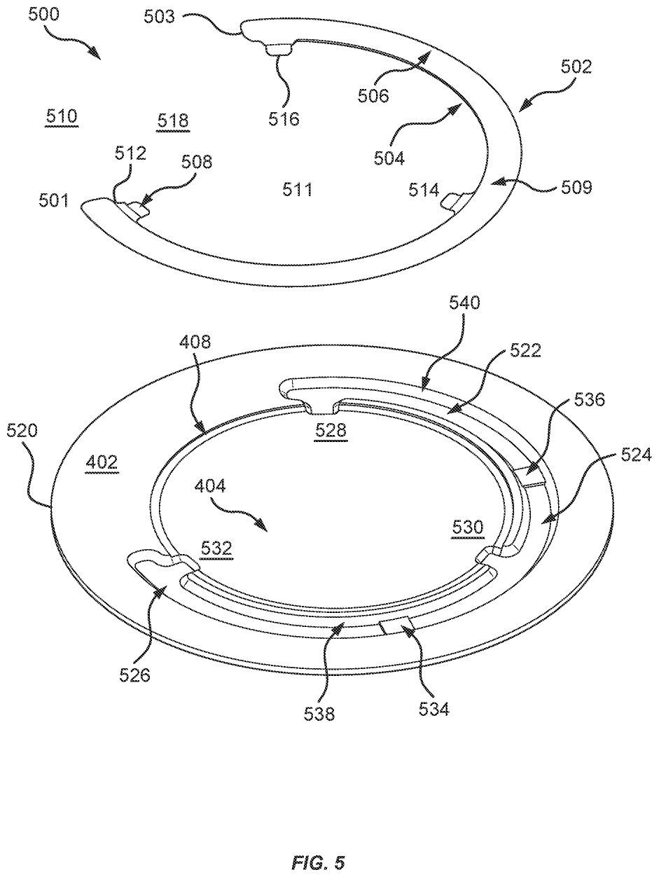

FIG. 5 illustrates a perspective view of a susceptor 500, according to another embodiment, that is suitable for use in the processing chamber 200, among others. The susceptor 500 includes a base part 520 and a detachable part 510. The shape and size of the susceptor 500 are generally similar with that of the susceptor 306. Comparing to the susceptor 306, which is a single piece, the susceptor 500 includes multiple detachable pieces. For example, the base part 520 and the detachable part 510 of the susceptor 500 are detachable. A substrate can be supported by the detachable part 510. Thus, when the detachable part 510 is lifted up by a plurality of lift pins, the detachable part 510 lifts up the substrate that sits on a surface of the detachable part 510.

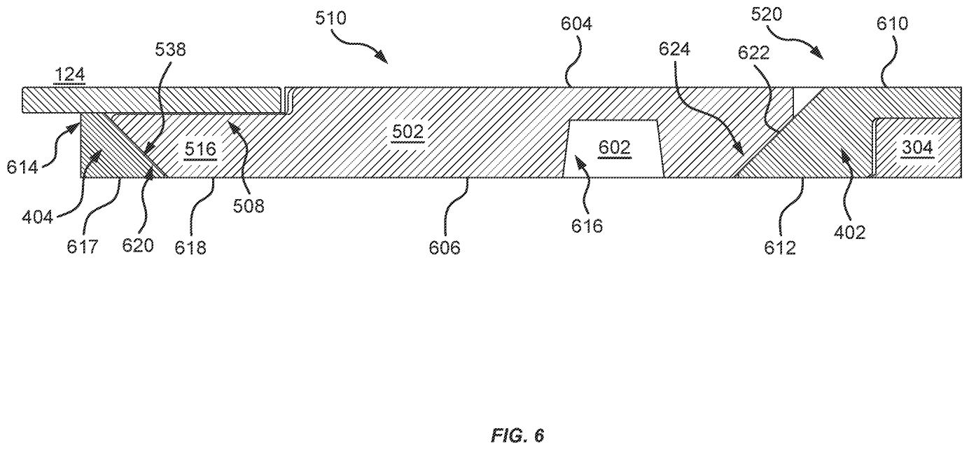

The detachable part 510 functions as a lift ring. The detachable part 510 includes an inner diameter 504 and an outer diameter 506, which is greater than the inner diameter 504. The detachable part 510 has sufficient material coverage to function as a blackout zone that blocks infrared (IR) light from entering the pin holes. The detachable part 510 includes an arc-shape rim 502 coupled with a plurality of protrusions 512, 514, and 516 disposed along the inner diameter 504. The plurality of protrusions 512, 514 and 516 include a top surface 508 that support a substrate 124. The top surface 508 of the protrusions 512, 514, and 516 is disposed below a top surface 509 of the arc-shaped rim 502. The plurality of protrusions 512, 514, and 516 extend from the inner diameter 504 inwardly along a horizontal plane into an inner side 511 of the detachable part 510. The detachable part 510 form an open arc with two opposing ends 501 and 503. Between the two opposing ends 501 and 503, an open segment 518 is formed and configured to allow a robotic blade 134 to move into the inner side 511. In an embodiment, a bottom surface 618 of the protrusions is disposed at the same level as the bottom surface 612 of the base rim 402 (shown in FIG. 6).

The base part 520 includes an inner pocket 404, a base rim 402, and a transitional rim 408. The base part 520 further includes a plurality of cutouts 522, 524, and 526 that couple with the detachable part 510. The plurality of cutouts 522, 524, and 526 are disposed mainly in the base rim 402. The plurality of cutouts 522, 524, and 526 further include cutouts 528, 530, and 532 that extend into the inner pocket 404. The cutouts 528, 530, and 532 are disposed in a close proximity to pin holes 207 of the body 302 (shown in FIG. 3). The plurality of cutouts 522, 524, and 526 include chamfered side surfaces 538 and 540 configured to couple with the side surfaces of the detachable part 510.

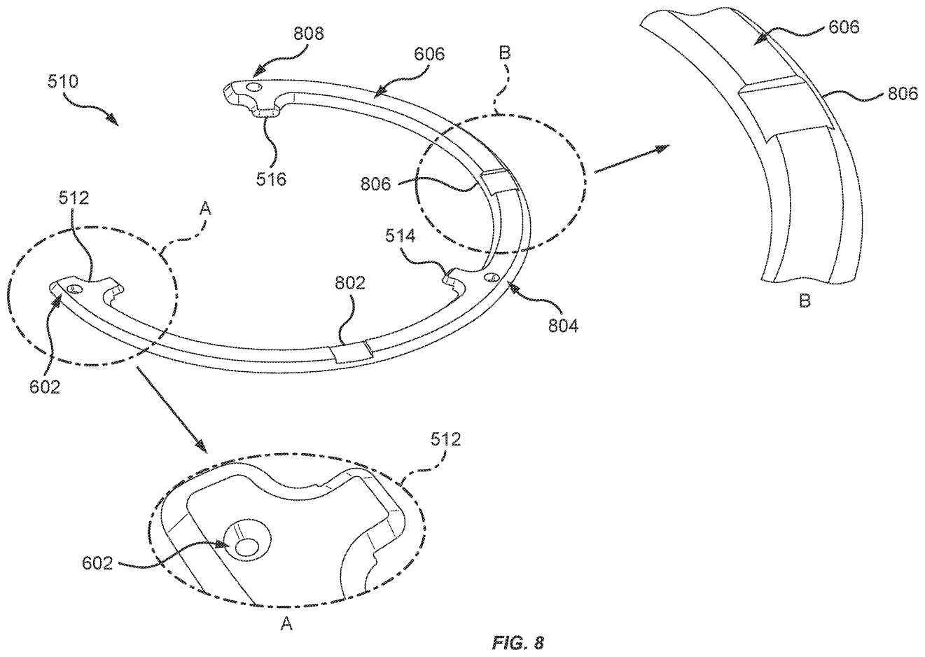

Continuing to refer to FIG. 5, the base part 520 includes a plurality of tabs 534 and 536 disposed within the cutouts 522, 524, and 526. The plurality of tabs 536 and 354 couple with slots 806 of the detachable part 510 (shown in FIG. 8) to support the detachable part 510. The tabs 534 and 536 couple the inner pocket 404 with the base rim 402.

FIG. 6 illustrates a schematic cross-sectional view of the susceptor 500 according to an embodiment. FIG. 6 illustrates a configuration when the detachable part 510 and the base part 520 are engaged with each other. In this configuration, a substrate 124 is supported by both the inner pocket 404 and the protrusion 516. To create an even support surface for the substrate 124, the protrusion 516 of the detachable part 510 is flushed with the inner pocket 404 of the base part 520. For example, the top surface 508 of the protrusion 516 is disposed at the same level as a top surface 614 of the inner pocket 404. The arc-shaped rim 502 of the detachable part 510 is flushed with the base rim 402 of the base part 520. For example, a top surface 604 of the arc-shaped rim 502 is disposed at the same level as the top surface 610 of the base rim 402.

Also shown in FIG. 6 is that the chamfered side surfaces 538 of the base part 520 engage with the side surfaces 620 of the detachable part 510. In an embodiment, the side surfaces 624 of the base rim 402 are inclined and form acute angles 622 with the top surface 604.

In an embodiment, the bottom surfaces 617, 618, 606, and 612 of the inner pocket 404, protrusion 516, arc-shaped rim 502, and the base rim 402 are disposed at the same level. The arc-shaped rim 502 is disposed above and coupled with the cylindrical ring 304.

Continuing to refer to FIG. 6, a depression 602 is disposed within the arc-shaped rim 502 and is aligned with pin holes 207 of the body 302. Comparing to the pin holes 207, the depression 602 functions a blind hole that blocks light emitted by the heating module 155 from passing through the detachable part 510.

The depression 602 is shaped like a frustum with a chamfered surface 616 extending from the bottom surface 606 to an inside of the depression 602. The diameter of the depression 602 is sized to be greater than a lift pin 232 such that the depression 602 can receive a lift pin and guide the lift pin into a desired position.

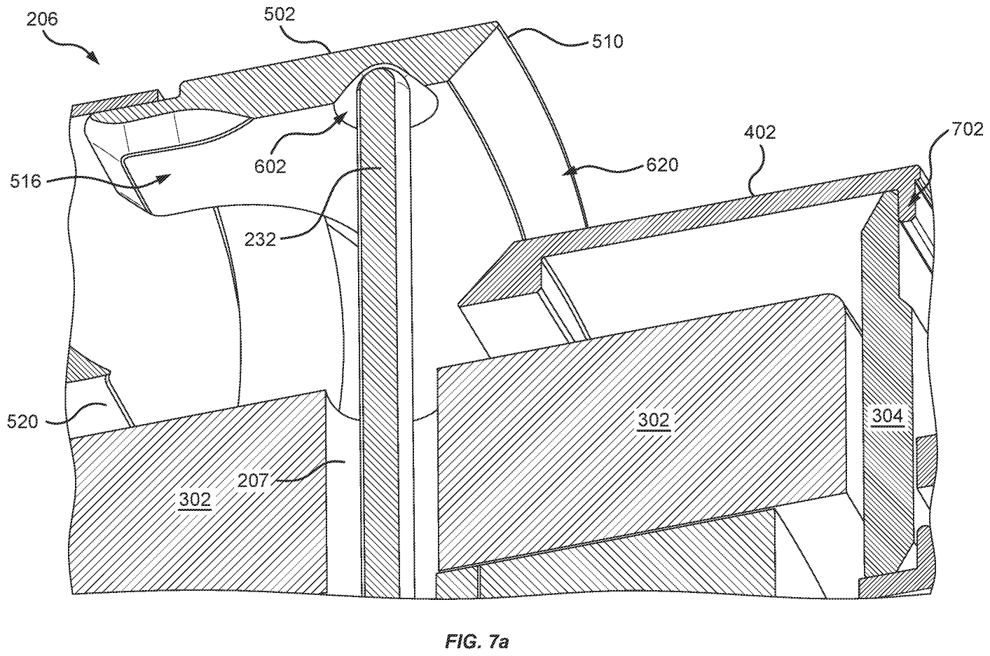

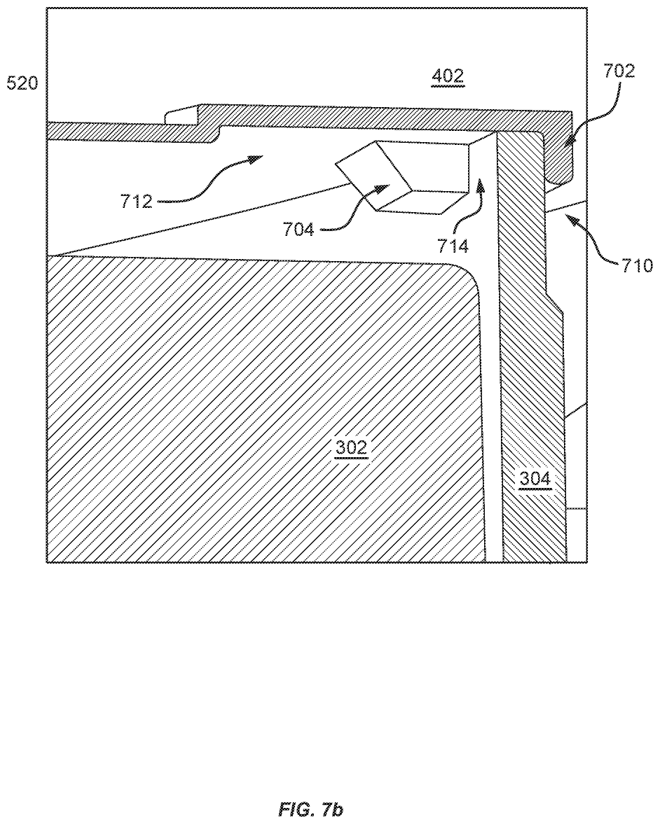

FIG. 7a illustrates a schematic perspective cross-sectional view of a substrate assembly 206 when the detachable part 510 of a susceptor 500 is lifted, according to an embodiment. The substrate support assembly 300 includes a body 302 coupled with a cylindrical ring 304. The base rim 402 is disposed on top of the cylindrical ring 304 and includes a skirt 702 extending downwardly to cover a portion of the cylindrical ring 304. The cylindrical ring 304 is disposed between the skirt 702 and the body 302. A lift pin 232 engages with the depression 602 of the arc-shaped rim 502 and lifts the detachable part 510 from the base part 520. The depression 602 is disposed above and aligned with the pin hole 207. The protrusion 516 extends under and contacts a substrate 124. The side surface 620 of the detachable part 510 is inclined toward the depression 602.

FIG. 7b illustrates a schematic cross-sectional view of a coupling mechanism 710 between the base part 520 and the cylindrical ring 304, according to an embodiment. Comparing with FIG. 7a, the base part 520 additionally includes a projection 704 disposed at a bottom surface 712 of the base rim 402. The projection 704 extends from the bottom surface 712 downwardly. The projection 702 has a side surface 714 facing the skirt 702 and is substantially parallel with the skirt 714. The gap between the side surface 714 and the skirt 702 is configured to be about the thickness of the cylindrical ring 304. When the base part 520 is coupled with the cylindrical ring 304, an upper portion of the cylindrical ring 304 can contact both the side surface 714 and the skirt 702 snugly, thus securing the base part 520 in place. In an embodiment, the projection 404 has a trapezoid shape. One side of the two parallel sides of the projection 704 contacts with the bottom surface 712 and has a greater length than the other side of the two parallel sides. The projection 704 could be of any shape as long as the side surface 714 generally conforms to the shape of the cylindrical ring 304.

FIG. 8 illustrates a schematic bottom view of the detachable part 510 and two callouts A and B showing details of certain configurations, according to an embodiment. The detachable part 510 includes a plurality of depressions 602, 804, and 808. According to an embodiment, three (3) depressions are disposed on the bottom surface at 120 degree intervals. The plurality of protrusions 512, 514, and 516 are disposed in a close proximity to the plurality of depressions 602, 804, and 808, respectively. As shown in Callout A, the depression 602 has a frustum-like shape. The detachable part 510 further includes a plurality of slots 802 and 806 disposed on the bottom surface 606 of the arc-shaped rim. As shown in Callout B, the plurality of slots 802 and 806 traverse the bottom surface 606 along a horizontal plane. The plurality of slots 802 and 806 are configured to engage with the tabs 534 and 536 (shown in FIG. 5).

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

1. A susceptor for a substrate support assembly of a processing chamber, the susceptor comprising:
a base part comprising a plurality of cutouts; and
a detachable part comprising an arc-shaped rim that comprises side surfaces configured to couple with the plurality of the cutouts,
wherein the arc-shaped rim further comprises an inner diameter, an outer diameter that is greater than the inner diameter, a first top surface, a first bottom surface; and a plurality of protrusions disposed along the inner diameter of the arc-shaped rim and comprising a second top surface that is disposed below the first top surface.

2. The susceptor of claim 1, wherein both the detachable part and the base part are made of graphite and coated with a layer of silicon carbide.

3. The susceptor of claim 2, wherein the first bottom surface comprises a plurality of depressions shaped like a frustum, and the plurality of the protrusions comprise a second bottom surface that is disposed at a same level as the first bottom surface, and wherein the plurality of protrusions extend from the inner diameter along a horizontal plane into the base part.

4. The susceptor of claim 1, wherein the arc-shaped rim forms a partial hoop with two opposing ends, and the arc-shaped rim further comprises angled side surfaces that form acute angles with the first top surface.

5. The susceptor of claim 1, wherein the base part comprises an inner pocket surrounded by a base rim that is taller than the inner pocket, the plurality of the protrusions are flushed with the inner pocket, and the arc-shaped rim is flushed with the base rim.

6. The susceptor of claim 5, wherein the base part comprises a plurality of tabs disposed within the plurality of cutouts and coupled with a plurality of slots disposed on the first bottom surface of the detachable part.

7. The susceptor of claim 6, wherein the plurality of cutouts comprise a first cutout in the base rim and a second cutout in the inner pocket.

8. The susceptor of claim 5, wherein the inner diameter of the arc-shaped rim is greater than a diameter of the inner pocket, and the outer diameter of the arc-shaped rim is smaller than a diameter of the base rim.

9. The substrate support assembly of claim 1 comprising:
a body surrounded by a cylindrical ring and comprising a plurality of pin holes.

10. The substrate support assembly of claim 9, wherein the susceptor comprises a body made of graphite and a surface layer of silicon carbide covering the graphite or comprises a body made of silicon carbide and a surface layer made of oxidized silicon carbide.

11. The substrate support assembly of claim 9, wherein the base part comprises a base rim disposed on top of the cylindrical ring, the base part further comprises a skirt extending downwardly from the base rim, and the cylindrical ring is disposed between the body and the skirt.

12. The substrate support assembly of claim 11, wherein the base part comprises an inner pocket surrounded by the base rim, the plurality of the protrusions is flushed with the inner pocket, and the arc-shaped rim is flushed with the base rim.

13. The substrate support assembly of claim 9, wherein the arc-shaped rim forms a partial hoop with two opposing ends, side surfaces of the arc-shaped rim form acute angles with the first top surface, and the first bottom surface comprises a plurality of depressions shaped like a frustum and aligned with the plurality of pin holes.

14. A detachable part of a susceptor for supporting a substrate in a processing chamber, the detachable part comprising:
an arc-shaped rim comprising an inner diameter, an outer diameter that is greater than the inner diameter, a first top surface, and a first bottom surface; and
a plurality of protrusions disposed along the inner diameter of the arc-shaped rim and comprising a second top surface that is disposed below the first top surface.

15. The detachable part of claim 14, wherein the plurality of the protrusions comprise a second bottom surface that is disposed at a same level as the first bottom surface, and the first bottom surface further comprises comprising a plurality of depressions shaped like a frustum.

16. The detachable part of claim 15, wherein the plurality of protrusions extend from the inner diameter along a horizontal plane into an inner side of the detachable part.

17. The detachable part of claim 14, wherein the plurality of depressions comprise a chamfered surface extending from the first bottom surface into the plurality of depressions.

18. The detachable part of claim 14, wherein the arc-shaped rim further comprises angled side surfaces that form acute angles with the first top surface.

19. The detachable part of claim 18, wherein the arc-shaped rim forms a partial hoop with two opposing ends, and the arc-shaped rim further comprises a plurality of slots disposed on and traversing the first bottom surface.

20. The detachable part of claim 14, wherein the detachable part comprises a body made of graphite and a surface layer of silicon carbide covering the graphite or comprises a body made of silicon carbide covered by an oxidation layer of silicon carbide.
